(19) United States
(12) Patent Application Publication
(10) Pub. No.: US 2008/0283280 A1
(43) Pub. Date: Nov. 20, 2008

(54) Method for Connecting Printed Circuit Boards

(76) Inventors: Kohichiro Kawate, Tokyo (JP); Yoshihisa Kawate, Kanagawa pref (JP)

Correspondence Address: 3M INNOVATIVE PROPERTIES COMPANY, PO BOX 33427, ST. PAUL, MN, 55133-3427, US

(21) Appl. No.: 12/092,773

(22) PCT Filed: Nov. 9, 2006
(86) PCT No.: PCT/US06/43658

§ 371 Date: May 6, 2008

(30) Foreign Application Priority Data
Nov. 15, 2005 (JP) 2005-330433

(51) Int. Cl. H05K 1/14; B29C 65/54

(52) U.S. Cl. 174/255; 156/292

(57) ABSTRACT

To provide a method for connecting printed circuit boards with high connection reliability, while avoiding the problem of shorting even with a fine pitch. A method for connecting printed circuit boards (PCB) containing metal wiring, or connecting a printed circuit board (PCB) containing metal wiring with a metal lead wire or a metal contact, which method includes a step of thermocompression bonding of an adhesive film with connectors, the adhesive film being composed of an adhesive composition comprising a thermoplastic resin and organic particles, wherein the viscosity decreases as the applied thermocompression force increases at a temperature of 100-250° C.

### TECHNICAL FIELD

The present invention relates to a method for connecting printed circuit boards (PCB) (including flexible type and rigid type) containing metal wiring, or connecting a printed circuit board (PCB) containing metal wiring with a metal lead wire or a metal contact (for example, a metal contact in an electric connector).

### BACKGROUND

Methods employing soldering, anisotropic conductive adhesives and mechanical connectors have been used in the past as techniques for establishing electrical connection of terminals between circuit boards. Soldering requires temperatures of 260° C. and above, and the peripheral mounted parts or even the boards themselves sometimes cannot withstand such high temperatures. It is necessary to consider the mounting order and mounting positions of parts so that parts with low heat resistance are not exposed to the heat, and this has reduced the mounting density and placed restrictions on the types of parts that can be mounted. Formation of soldering bridges between terminals is another problem that renders it difficult to achieve high-density mounting with a pitch of 0.3 mm or less. An additional problem is the need for high temperatures of 260° C. and above to terminate connections for repair. Anisotropic conductive adhesives provide continuity by conductive particles in resins, but their high connection resistance has been a problem. Furthermore, this method is inconvenient because organic solvents and the like are necessary for termination of continuity for repair. On the other hand, conventional mechanical connectors facilitate repair but have problems similar to soldering, since soldering must be used for mounting of the connectors themselves. In addition, especially in case of mechanical connectors, because they have a mechanical structure which allows connection, the connectors themselves must be of a certain size which can be disadvantageous for high-density mounting and low-profile mounting, such that high-density mounting with a pitch of 0.3 mm or less and low-profile connection of 0.8 mm or less cannot be achieved.

Japanese Unexamined Patent Publication (Kokai No. 62-184788) describes a method in which connection is established by running a pair of opposing conductors through an insulating adhesive, but this technique does not provide a “plastic flow property” whereby the viscosity of the adhesive decreases only when a high stress is applied, nor is it suitable for convenient repair.

Japanese Unexamined Patent Publication (Kokai) No. 62-184788

### SUMMARY OF THE INVENTION

It is an object of the invention to provide a method for connecting circuit boards which is highly reliable and does not cause shorting problems even with a fine pitch, as compared to conventional connection of circuit boards by soldering or connection of circuit boards with anisotropic conductive compositions.

According to one mode, the present invention provides

(1) a method for connecting printed circuit boards (PCB) containing metal wiring, or connecting a printed circuit board (PCB) containing metal wiring with a metal lead wire or metal contact, which is a connection method combining solid-phase bonding or solid-phase contact between metal. with connection using an adhesive, the method comprising the steps of:

(i) placing an adhesive film between the connecting portions of metal wiring of printed circuit boards (PCB) or between the connecting portion of metal wiring of a printed circuit board (PCB) and a metal lead wire or metal contact, and

(ii) thermocompression bonding the connecting portion(s) and/or the metal lead wire or metal contact with the adhesive film at a temperature and pressure sufficient to push away the adhesive film for electrical contact between the connecting portions of the opposing circuit boards or between the connector of the circuit board and the metal lead wire or metal contact, the temperature being one which does not melt the metal wiring or metal lead wire or metal contact,

wherein the adhesive film is composed of an adhesive composition comprising a thermoplastic resin and organic particles and its viscosity decreases as the applied thermocompression force increases at a temperature of 100-250° C.

The invention further provides (2) the method of (1) above wherein said adhesive film exhibits a peel adhesive strength of 5 N/cm or greater after thermocompression bonding for 1-30 seconds at a temperature of 100-250° C., as determined by a 90° peel test at 25° C. with a peel speed of 60 mm/min.

The invention further provides (3) the method of (1) or (2) above wherein the metal wiring or metal lead wire has its outermost periphery plated with a noble metal.

The invention still further provides (4) the method of (1) to (3) above wherein the connection formed in step (ii) is terminated by application of a force with heat on the printed circuit boards (PCB) or the printed circuit board and metal lead wire, and then connection is reestablished in the same way as step (ii).

The invention still further provides (5) the method of any one of (1) to (4) above, wherein the printed circuit board (PCB) has protrusions formed on the connectors of the metal wiring in order to facilitate connection.

The invention still further provides (6) the method of any one of (1) to (5) above, wherein in step (ii), connection is established by thermocompression bonding under application of a load of 1-10 MPa for 1-30 seconds at a temperature of 100-250° C.

The invention still further provides (7) the method of any one of (1) to (6) above, wherein in step (ii), the load is applied while introducing ultrasonic waves.

The invention still further provides (8) the method of (4) above, wherein the connection established in step (ii) is terminated at a temperature of no higher than 250° C. and then connection is reestablished in the same way as step (ii).

The invention still further provides (9) the method of any one of (1) to (8) above, wherein the adhesive film comprises organic particles with a diameter of no greater than 10 μm at 25-90 parts by weight to 100 parts by weight of the adhesive composition.

The invention still further provides (10) the method of any one of (1) to (9) above, wherein a polyester resin is further combined with the adhesive composition, so that tackiness is exhibited by the adhesive composition after heating for a short period.

The invention still further provides (11) the method of any one of (1) to (10) above, wherein the adhesive film is formed on the printed circuit board (PCB) in a screen printing step.

The invention still further provides an electronic part or electronic device comprising a printed circuit board connected by the method of any one of (1) to (11) above.

Throughout the present specification, “90° peel adhesive strength” will refer to the peel adhesive strength determined by placing the adhesive film on a glass epoxy panel (FR-4), situating thereover a rolled copper foil with a width of 10 mm and a thickness of 35 μm and thermocompression bonding these at a prescribed temperature and pressure for a prescribed period of time, and then measuring the load while peeling the edge of the copper foil at an angle of 90° with respect to the glass epoxy panel and a peel speed of 60 mm/min.

According to the invention, connection is established with an adhesive film lying between each of the connecting portions, unlike connection between FPCs and other boards by conventional soldering, and therefore problems of shorting do not occur even with a fine pitch between connecting portions. In addition, since the connecting portions are supported and anchored by the adhesive film, the connections are not terminated by external stress and the reliability of connection is therefore increased.

Moreover, since the viscosity of the adhesive film decreases as the applied thermocompression force increases at the connecting temperature, the flow property increases during the thermocompression bonding procedure, and reliable connections can be established between the metal sections of the connecting portions. At the same time, the connection reliability is high since the connections are not terminated unless a large pressure force and excessive heat are applied or either of them is excessively applied after connection.

The connecting method of the invention can therefore be used for connection between the module boards and main boards of miniature electronic devices which require high-density mounting, such as cameras and liquid crystal panels in cellular phones or digital cameras, or connection of other boards between such module boards.

According to the connection method of the invention, connections can be established at lower temperatures than by soldering. Furthermore, reconnection can be easily established after termination of connections in cases of defective boards or defective parts on boards, or in cases of failed connections. If a mechanical connector is not used, connecting structure portion can be very low profile.

### BRIEF DESCRIPTION OF THE DRAWINGS

FIGS. 1A-1C show a process diagram showing the connection method of the invention.

### DETAILED DESCRIPTION

The present invention will now be explained based on the following embodiments, with the understanding that the invention is not limited to these specifically described embodiments.

### Printed Circuit Board (PCB)

The printed circuit board (PCB) used for the invention may be any suitable circuit board, such as a circuit board based on a glass epoxy, a circuit board based on an aramid, a circuit board based on a bismaleimide-triazine (BT resin), a glass panel or ceramic board having a wiring pattern formed with ITO or fine metal particles, a rigid circuit board such as a silicon wafer having metal conductor connecting portions on the surface, or a flexible circuit board. The printed circuit board (PCB) may also be connected to a metal lead wire. Also, the other end of the metal lead wire may be connected to a separate circuit board.

### Method of Connecting Printed Circuit Boards

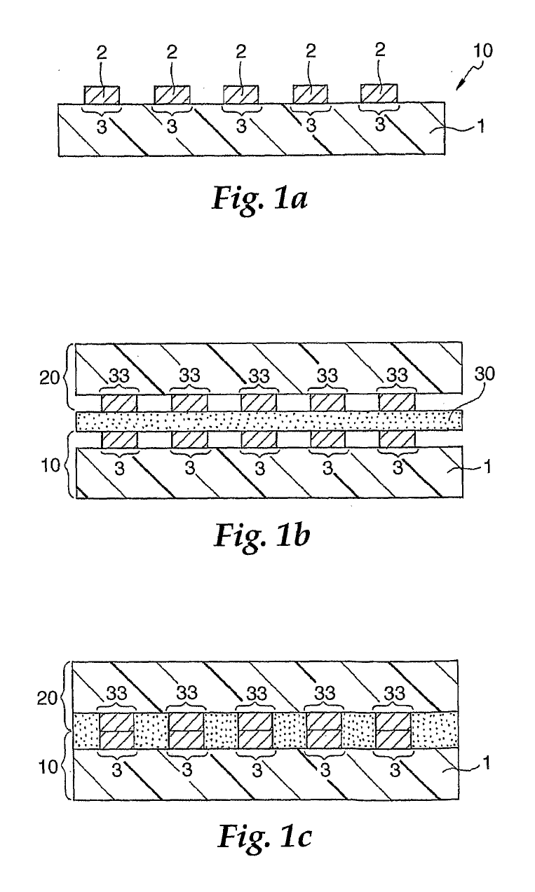

The procedural order for a method of connecting two printed circuit boards (PCB) or connecting a printed circuit board (PCB) and a metal lead wire or metal contact according to the invention will now be explained. FIG. 1 is a diagram illustrating connection between two printed circuit boards (PCB), but there is no limitation to this mode and the same connection may of course be established between a printed circuit board (PCB) and a metal lead wire or metal contact.

FIG. 1 is a process diagram showing the connection method of the invention. First, a printed circuit board (PCB) 10 having metal wiring 2 formed on a support 1 is prepared (step (a)). Next, a second printed circuit board (PCB) 20 is prepared for connection to the PCB 10, and the connecting portion 3 of the PCB 10 and the connecting portion 33 of the second printed circuit board (PCB) 20 are positioned and attached together using an adhesive film 30 (step (b)). The laminate comprising the attached PCB 10, adhesive film 30 and second printed circuit board (PCB) 20 is thermocompression bonded to establish electrical connection between the connecting portion 3 of the PCB 10 and the connecting portion 33 of the second printed circuit board (PCB) 20 (step (c)). The adhesive film 30 may be pre-bonded to the PCB 10 or 20 by appropriate coating means such as screen printing. The adhesive film 30 may also be pre-bonded on the PCB 10 or 20 by thermocompression bonding under the same conditions as for connection of the PCBs.

The material of the metal wiring or metal lead wire or metal contact may be a conductor such as solder (for example, Sn—Ag—Cu), copper, copper alloy, nickel, gold or the like. From the standpoint of connectivity, surface finishing may be carried out by plating with a material such as tin, gold, nickel, nickel/gold alloy or the like. The metal wiring or metal lead wire or metal contact is anchored by the adhesive together with solid-phase bonding or solid-phase contact, thereby forming a connection. When the metal wiring or metal lead wire or metal contact is plated on the outer periphery with a noble metal such as gold, formation of a solid-phase joint is preferred. The support of the PCB may be a rigid base such as a glass epoxy board, or it may be a flexible base such as a polyimide film. Protrusions formed in the metal wiring will increase the pressure at the points of contact during connection, thus improving the connection reliability. Protrusions can be formed on the printed circuit board by pressing a mold with irregularities onto the printed circuit board.

The thermocompression bonding may be accomplished using a heat bonder, such as a pulse heat bonder or ceramic heat bonder capable of heating and pressurization. The thermocompression bonding is carried out by compression with a heated plate. The temperature and pressure for thermocompression bonding is determined by the selected composition of the metal wiring and the resin composition of the adhesive film, and is not restricted. Specifically, the thermocompression bonding is carried out at a temperature which does not melt the metal wiring to be connected, and at a temperature and pressure sufficient for electrical contact between the metal wiring. For the invention, it is generally preferred to use an adhesive film with a softening point of about 100° C. or higher. Thermocompression bonding is usually carried out for 1-30 seconds at a temperature of 100-250° C. and a pressure of 1-10 MPa, for connection between metal wirings or between a metal wiring and metal lead wire or metal contact. Ultrasonic waves may also be used in addition to the pressurization for connection. When ultrasonic waves are used, the vibration acts on the adhesive film to produce a shear stress, thus lowering the viscosity of the adhesive composition and facilitating connection.

Once connection has been established between the formed metal wirings or between the metal wiring and metal lead wire or metal contact, it is not terminated even at a high use temperature of about 100° C. However, since the adhesive film exhibits reduced viscosity and a flow property when a force is applied to the connecting portion, it is possible to terminate a formed connection by applying force to the connecting portion, and connection can be reestablished by thermocompression bonding. This is because the adhesive film used for the invention has a plastic flow property due to the inclusion of organic particles. The termination will usually be accomplished at no higher than 250° C., a temperature which can be withstood by mounted parts and circuit boards.

An adhesive film used for the invention will now be described. According to the invention, an adhesive film made of an adhesive composition comprising a thermoplastic resin and organic particles is used. The thermoplastic resin is a resin which softens or melts at a temperature of 100° C. or above, and the organic particles are particles made of a material as described below, which impart a plastic flow property to the adhesive composition, or in other words, which impart a function whereby the viscosity decreases with application of pressure at the thermocompression temperature. The adhesive film preferably exhibits a peel adhesive strength of 5 N/cm or greater after thermocompression bonding on the target printed circuit board (for example, a glass epoxy board (FR-4)) for 1-30 seconds at a temperature of 100-250° C., as determined by a 90° peel test at 25° C. at a peel speed of 60 mm/min.

The thermoplastic resin composing the adhesive film exhibiting a plastic flow property is not particularly restricted, and it may be a base polymer commonly used for hot melt adhesives. As such thermoplastic resins there may be mentioned styrenated phenol, ethylene-vinyl acetate copolymer, low-density polyethylene, ethylene-acrylate copolymer, polypropylene, styrene-butadiene block copolymer, styrene-isoprene copolymer and phenoxy resins, preferably having a softening point of 100° C. or higher. The adhesive composition preferably comprises a polyester resin. This is because a polyester resin can produce a pressure-sensitive adhesive property in the adhesive composition after heating the adhesive film for a short period.

The adhesive film used for the invention preferably has a viscosity in the range of 500-20,000 Pa·s under thermocompression bonding conditions. The “adhesive film viscosity” is determined by placing an adhesive film sample with radius a (m) between two horizontal plates and measuring the thickness (h(t)) of the adhesive film after time t (sec) upon application of a constant load F (N) at measuring temperature T (° C.), and it is calculated by the following formula:

h(t)/h₀=[(4h₀²Ft)/(3πηa⁴)+1]^{-1/2}

(wherein h₀ is the initial thickness (m) of the adhesive film, h(t) is the thickness (m) of the adhesive film after t seconds, F is the load (N), t is the time (sec) from initial application of the load F, η is the viscosity (Pa·s) at the measuring temperature T (° C.), and a is the radius (m) of the adhesive film). If the viscosity is 500 Pa·s or below under the thermocompression bonding conditions, the adhesive film will run and satisfactory connection will not be possible. On the other hand, if the viscosity of the adhesive film is too high, it will be difficult to push away the resin from between the wiring conductors of the connectors even with a high pressure.

The adhesive composition used for the adhesive film preferably comprises organic particles at 25-90 parts by weight with respect to 100 parts by weight of the aforementioned adhesive composition. Addition of the organic particles will allow the resin to exhibit a plastic flow property.

The added organic particles may be particles made of acrylic resin, styrene-butadiene resin, styrene-butadiene-acrylic resin, melamine resin, melamine-isocyanuric acid complex, polyimide, silicone resin, polyetherimide, polyethersulfone, polyester, polycarbonate, polyetherether ketone, polybenzimidazole, polyarylates, liquid crystal polymers, olefin resins, ethylene-acrylic copolymers and the like, and their sizes are no greater than 10 μm and preferably no greater than 5 μm.

### EXAMPLES

### 1. Preparation of Rigid Circuit Board (PCB) And Flexible Printed Board (FPC)

A rigid circuit board (PCB) and flexible printed board (FPC) were prepared in the following manner.
PCB: Base material: FR-4 (0.4 mm), Metal Wiring: gold/nickel/copper 0.3 μm/5 μm/18 μm

Wiring width (L)/Distance between Wirings (S)=100 μm/100 μm, 50 circuits
FPC: Base material: Polyimide (25 μm), Metal wiring: gold/nickel/copper =0.3 μm/1.5 μm/18 μm

Wiring width (L)/Distance between wirings (S)=100 μm/100 μm, 50 circuits

Protrusions were formed on the FPC circuit face by pressing with a die having the following form.

Mold: SKD-11, commercially available from Ohtake Seisalcusho K.K. Gifu-ken, Japan, comprising 8 linear grooves with 200 μm pitch, 30 μm height.

Press: The linear protrusions and FPC circuit were arranged orthogonally and pressed with a 400 kgf load.

### 2. Fabrication of Adhesive Film

The composition listed in Table 1 was prepared by stirring at room temperature and then coated onto a polyethylene terephthalate (PET) film and dried for 30 minutes in an oven at 100° C. to obtain an adhesive film with a thickness of 25 μm.

TABLE 1
Adhesive composition (parts by wt.)

| | | | | Organic particle |
|---|---|---|---|---|
| | TP294 | ED512B | Organic particles | addition |
| Example 1 | 15 | 2 | EXL2314 | 13 |
| Example 2 | 15 | 3 | EXL2314 | 20 |
| Example 3 | 15 | 3 | MC600 | 13 |
| Comp. Ex. 1 | 15 | 2 | none | — |

Organic particles 1 EXL2314: acrylic particles, KUREHA PARALOID EXL, Kureha Chemical Industry Co., Ltd.
Organic particles 2 MC600: Melamine-isocyanuric acid complex, Nissan Chemical Industry Co., Ltd.
Saturated polyester resin: TP-294, The Nippon Synthetic Chemical Industry Co., Ltd., Nichigo POLYESTER
Styrenated phenol: ED-512B, Asahi Denka Co., Ltd., ADEKA GLYCIROL

### 3. Measurement of Adhesive Film Viscosity

The viscosity of the film was measured at the temperatures and pressures shown in Table 2 below. The viscosity measurement was carried out in the following manner. First, the adhesive film sample was cut into a circular form with radius a (m) (0.005 m), the adhesive film sample was situated between polyimide films with a thickness of 12.5 μm, and the viscosity was calculated from the following formula based on the thickness (h(t)) of the adhesive film after time t (sec) upon application of a constant load F (N):

h(t)/h₀=[(4h₀²Ft)/(3πηa⁴)+1]^{-1/2}

(wherein h₀ is the initial thickness (m) of the thermosetting adhesive film, h(t) is the thickness (m) of the adhesive film after t seconds, F is the load (N), t is the time (sec) from initial application of the load F, η is the viscosity (Pa·s) at the measuring temperature T (° C.), and a is the radius (m) of the adhesive film). The results are shown in Table 2.

### 4. Measurement of Adhesive Strength

The adhesive film was placed on a 2 mm-thick glass epoxy board (FR-4), and then a rolled copper foil with a width of 10 mm and a thickness of 35 μm was situated thereover prior to 20 seconds of pressing with 200 kgf at 150° C. for bonding. The load while peeling the edge of the copper foil at an angle of 90° with respect to the glass epoxy panel and a peel speed of 60 mm/min was then measured as the peel adhesive strength. The results are shown in Table 2.

TABLE 2

| | | | Adhesive |
|---|---|---|---|
| | Viscosity (P · as) | Viscosity (P · as) | strength |
| | (150° C., 2.2 MPa) | (150° C., 5.9 MPa) | (N/cm) |
| Example 1 | 3170 | 1243 | 21 |
| Example 2 | 4930 | 1289 | 22 |
| Example 3 | 2616 | 1336 | 12 |
| Comp. Ex. 1 | 180 | 232 | 9 |

### 5. Electrical Resistance of Connected Boards

The adhesive film was placed over the FPC circuit face on which protrusions had been formed in the manner described above, and laminated by hot pressing at 120° C. for pre-adhesion of the adhesive film on the FPC. The PCB was then situated against the side of the laminate bearing the adhesive film, and connected with a load of 20 kgf (load pressure: 10 MPa) using the following temperature profile.

Holding for 5 seconds at a temperature of 175° C. or higher.

Maximum temperature: 200° C.

Release of load applied to heater at 145° C.

The value of the connection resistance between the PCB and FPC circuits obtained in the manner described above was measured using a milliohmeter according to the 4-point probe method. The results are shown in Table 3. All of the circuits were confirmed to be connected with a resistance of no greater than 1 Ω, and to have environmental resistance (aging resistance) under the conditions shown below. The results are shown in Table 3 below.

Heat cycle: 500 cycles of −40° C./30 min+80° C./30 min

Force was applied to the electrical connections established by the aforementioned method while heating on a heater at 150° C. The method allowed termination of the connections without inflicting damage to the PCB or FPC. The FPC and PCB whose electrical connections had been terminated were then re-connected under the same conditions as previously, and the connection resistance after repair was measured. The results are shown in Table 3 below.

TABLE 3

| | Connection resistance | Connection | Connection |
|---|---|---|---|
| | (Ω) | resistance (Ω) | resistance (Ω) |
| | (Initial) | (After aging) | (After repair) |
| Example 1 | 0.1 | 0.12 | 0.1 |
| Example 2 | 0.1 | 0.11 | 0.1 |
| Example 3 | 0.1 | 0.12 | 0.1 |
| Comp. Ex. 1 | no connection possible | — | — |

1. A method for connecting printed circuit boards (PCB) containing metal wiring, or connecting a printed circuit board (PCB) containing metal wiring with a metal lead wire or metal contact, which is a connection method combining solid-phase bonding or solid-phase contact between metal with connection using an adhesive, the method comprising the steps of:
(i) placing an adhesive film between the connecting portions of metal wiring of printed circuit boards (PCB) or between the connecting portion of metal wiring of a printed circuit board (PCB) and a metal lead wire or metal contact, and
(ii) thermocompression bonding said connecting portion(s) and/or said metal lead wire or metal contact with said adhesive film at a temperature and pressure sufficient to push away the adhesive film for electrical contact between the connecting portions of the opposing circuit boards or between the connecting portion of the circuit board and the metal lead wire or metal contact, the temperature being one which does not melt the metal wiring, or metal lead wire or metal contact,
wherein said adhesive film is composed of an adhesive composition comprising a thermoplastic resin and organic particles and its viscosity decreases as the applied thermocompression force increases at a temperature of 100-250° C.

2. The method of claim 1 wherein said adhesive film exhibits a peel adhesive strength of 5 N/cm or greater after thermocompression bonding for 1-30 seconds at a temperature of 100-250° C., as determined by a 90° peel test at 25° C. with a peel speed of 60 mm/min.

3. The method of claim 1, wherein said metal wiring or metal lead wire has its outermost periphery plated with a noble metal.

4. The method of claim 1, wherein the connection formed in step (ii) is terminated by application of a force with heating on the printed circuit boards (PCB) or the printed circuit board and metal lead wire, and then connection is reestablished in the same way as step (ii).

5. The method of claim 1, wherein the printed circuit board (PCB) has protrusions formed on the connecting portions of the metal wiring in order to facilitate connection.

6. The method of claim 1, wherein in step (ii), connection is established by thermocompression bonding under application of a load of 1-10 MPa for 1-30 seconds at a temperature of 100-250° C.

7. The method of claim 1, wherein in step (ii), the load is applied while introducing ultrasonic waves.

8. The method of claim 4, wherein the connection established in step (ii) is terminated at a temperature of no higher than 250° C. and then connection is reestablished in the same way as step (ii).

9. The method of claim 1, wherein said adhesive film comprises organic particles with a diameter of no greater than 10 μm at 25-90 parts by weight to 100 parts by weight of the adhesive composition.

10. The method of claim 1, wherein a polyester resin is further combined with the adhesive composition, so that tackiness is exhibited by the adhesive composition after beating for a short period.

11. The method of claim 1, wherein said adhesive film is formed on said printed circuit board (PCB) in a screen printing step.

12. An electronic part or electronic device comprising a printed circuit board connected by the method of claim 1.
